(19) United States
(12) Patent Application Publication
(10) Pub. No.: US 2013/0207651 A1
(43) Pub. Date: Aug. 15, 2013

(54) FLUXGATE SENSOR

(71) Applicants: Martin Rückert, Wurzburg (DE); Florian Fidler, Wurzburg (DE); Oliver Radestock, Wurzburg (DE); Steffen Lother, Guntersleben (DE)

(72) Inventors: Martin Rückert, Wurzburg (DE); Florian Fidler, Wurzburg (DE); Oliver Radestock, Wurzburg (DE); Steffen Lother, Guntersleben (DE)

(73) Assignees: MRB Forschungszentrum Magnet - Resonanz -Bayem e.V, Wurzburg (DE); Hochschule fur angewandtl Wissenschaften Fachhochschule Wurzburg-Schweinfurt, Wurzburg (DE)

(21) Appl. No.: 13/822,681

(22) PCT Filed: Aug. 19, 2011
(86) PCT No.: PCT/EP11/04188

§ 371 Date: Apr. 23, 2013

(30) Foreign Application Priority Data
Oct. 1, 2010 (DE) 10 2010 047 270.0

(51) Int. Cl. G01R 33/04

(52) U.S. Cl. CPC G01R 33/04
USPC 324/258

(57) ABSTRACT

A fluxgate sensor has a driver coil, a signal coil, and a magnetic core that magnetically couples the driver coil and the signal coil. A magnetic field detector that can be positioned in a remote area is provided. The magnetic field detector is connected to a magnetic field generator positioned in the vicinity of the magnetic core by a transmission line, where the magnetic field of the magnetic field generator is superposed with the driver field.

The invention relates to fluxgate sensor comprising a driver coil, a signal coil and a magnetic core, via which the driver coil and the signal coil are magnetically coupled. The invention further relates to an array arrangement having such fluxgate sensors.

A fluxgate sensor of the type mentioned at the beginning is used to measure magnetic fields into the picotesla region, a frequency range of down to a few kilohertz being covered. The nonlinear transmission method of a ferromagnet is utilized for this purpose. The driver coil generates an alternating magnetic field, the magnetization of the magnetic core being driven into saturation thereby. If a sinusoidal signal is coupled into the driver coil, the nonlinearity of the magnetization causes a rectangular distortion of the flux density in the magnetic core whose temporal change is detected by the signal coil. Because of the given nonlinear distortion, the decoupled signal comprises the odd harmonics of the fundamental wave.

If a magnetic field to be measured is superposed, this leads to an asymmetrical component with reference to the driver field, since the measuring field adds or subtracts the driver field, depending on phase. This gives rise to even harmonics in the spectrum of the signal decoupled with the signal coil, which can be clearly distinguished from the odd harmonics. The measuring field is reconstructed by an appropriate signal analysis, and determined sensitively therewith.

Owing to their robustness and their precision, fluxgate sensors are used, in particular, to observe geomagnetic fields, where the aim is to automate data acquisition. A fluxgate sensor offers the option of attaining good measurement results by simple means. The efficiency of the signal detection is maintained for a fluxgate sensor up to signal frequencies of below 100 Hz, and this enables the detection system to be constructed with cost effective electrical and electronic means.

It is a disadvantage that owing to its electromagnetic properties, a fluxgate sensor can itself disturb the magnetic fields to be measured. For example, the magnetic core of the fluxgate sensor couples onto a magnetic field to be measured, and disturb the latter through its own magnetization. The electromagnetic properties of the fluxgate sensor also, in particular, disturb magnetic field measurements such as are required to obtain signals in magnetic resonance spectroscopy (MR) or in methods for imaging by means of magnetic particles (magnetic particle imaging: MPI).

In MR spectroscopy, a static magnetic field is generated in which the magnetic moments of the atomic nuclei are predicative. The emission of a high-frequency magnetic field with the Larmor frequency dependent on the static magnetic field induces flip-over processes of the magnetic moments that lead to a measurable transverse magnetization. Spatial coding results from a gradient magnetic field.

In MPI spectroscopy, macroscopic magnetic moments of particles are influenced by an exciting magnetic field. The use of the saturation effect of the magnetization of the particles for spatial imaging of the given distribution is known in this regard from the article “Tomographic Imaging Using the Nonlinear Response of Magnetic Particles”, Bernhard Gleich, Jurgen Weizenecker, Nature Vol. 435, Jun. 30, 2005. It is thereby possible to separate the measuring signal easily from the excitation signal as for the fluxgate signal. For the spatial coding, a strong gradient magnetic field with a field free point at the measurement volume is generated. Since the magnetization of the particles reaches its saturation value outside the field free point, it is effectively only those particles that are located in the field free point which contribute to the imaging.

In accordance with the German patent application DE 10 2010 013 900, which is still unpublished, imaging in MPI spectroscopy is performed by irradiating a magnetic rotating field in addition to which the magnetic moments of the particles rotate asynchronously. A measurable superpositioned transverse magnetization can be generated by specific irradiation of additional magnetic fields, or by variation of the rotating field. A gradient magnetic field is used for spatial coding.

It is an object of the invention to specify a fluxgate sensor of the type mentioned at the beginning that can be used without interference to measure sensitive magnetic fields, as are found, in particular, in MR spectroscopy or MPI spectroscopy.

This object is achieved according to the invention for a fluxgate sensor of the type mentioned at the beginning by providing a magnetic field detecting means that can be positioned in a remote area and is connected by means of a transmission line to a magnetic field outputting means that is positioned in the vicinity of the magnetic core and whose magnetic field is superposed with the driver field.

In other words, the invention proceeds from the consideration of spatially removing the electromagnetic driver and measuring part of the fluxgate sensor from the measuring area. This is achieved by providing a magnetic field detecting means that can be positioned in a remote area and picks up the magnetic field to be measured and to transmit via the transmission line to a magnetic field outputting means positioned at the driver and measuring part. The magnetic field outputting means is arranged in the vicinity of the magnetic core so that the output magnetic field is superposed effectively with the driver field.

The disturbing magnetic influence of the fluxgate sensor on the magnetic field to be measured is eliminated. The magnetic measuring field detected in a remote measurement space is transmitted to the actual measuring part of the fluxgate sensor by means of the transmission line. There, the transmitted measuring field is superposed on the driver field and can be separated from the measuring signal of the signal coil by spectral analysis as an even harmonic, and reconstructed.

An as yet unknown field of use is opened up for the sensitive and robust fluxgate sensor in the way described. In particular, it is possible to detect comparatively low-frequency and weak magnetic fields whose inductive coupling is difficult. This is the case, in particular, in low field MR spectroscopy, specifically terrestrial field MR spectroscopy, the terrestrial magnetic field being used as static magnetic field in the latter case. It follows that the Larmor frequency is at approximately 2.1 kHz by comparison with approximately 60 MHz for conventional MR spectroscopy. For MPI spectroscopy, the magnetic fields to be observed are present with a frequency between approximately 1 kHz to 1 MHz.

Whereas in the case of relatively low-frequency magnetic fields it is necessary to use high impedance coils with a high number of turns per unit length with respect to a sufficiently inductive coupling, this is not required for detection with a high sensitivity fluxgate sensor. Thus, in particular, low impedance coils with a comparatively low number of turns value at per unit can be used without any problem as magnetic field detecting means. The measuring signal is conducted in this case as current to the actual measuring area of the fluxgate sensor. Whereas typical measuring coils of MR spectroscopy have a high number of turns per unit length in the region of a few thousand turns, a coil that has only a few tens of turns suffices for coupling the measuring field for the fluxgate sensor as magnetic field detecting means. The construction of the measuring coils is hereby rendered more advantageous. The required overall space is substantially reduced. The size of the winding wire is increased and thus the electrical resistance is reduced.

In a preferred refinement of the fluxgate sensor, the transmission line is a flux conductor. Here, the magnetic field to be measured is coupled into one end of the flux conductor, and decoupled at the other end of the flux conductor in the measuring area of the fluxgate sensor. In other words, the ends of the flux conductor itself can form the magnetic field detecting means and the magnetic field outputting means. However, this need not necessarily be the case.

A magnetic flux conductor transmits the magnetic field to be measured through a magnetic or through an electromagnetic flux line. The flux conductor can, in particular, be designed as a so-called “Swiss roll” that comprises, for example, a copper coil rolled up with Teflon. The magnetic field detected at one end is decoupled again at the other end of the “Swiss roll” via electromagnetic induction effects. In this case, the signal profile as such remains. All that occur are transmission losses. The flux conductor can, on the other hand, also be designed as a ferro- or ferri-magnetic material, in which the magnetic field is guided with a low magnetic resistance. Again, magnetic field lenses can be used for particular guidance of the magnetic field coupled in relative to the measuring area of the fluxgate sensor.

In an alternative and equally preferred variant refinement of the fluxgate sensor, the transmission line is an electric signal line. In this case, the magnetic field to be measured is converted by the magnetic field detecting means into an electronic or electric signal. The electronic or electric signal is then transmitted via the electric signal line to the magnetic field outputting means and converted there again into the magnetic field. In this case, the transmission signal is present, in particular, in digital or analog form. An arbitrarily coded signal for transmission is also conceivable in principle. In a cost effective and practical refinement, the electric signal line is configured as a connecting line in which an inductively detected measuring signal is guided to the magnetic field outputting means as a current.

In an expedient refinement, the magnetic field detecting means and the magnetic field outputting means are designed as coils. As mentioned, owing to the high sensitivity of the fluxgate sensor in this case the coils are of low impedance design even for low frequencies, and are configured with a low number of turns per unit length. Here, furthermore, the impedances of the two coils are preferably matched to one another, and this is done, for example, by an appropriate variation in the number of turns per unit length.

In principle, it is sufficient for the invention to superpose the magnetic field generated by the magnetic field outputting means on the driver field in a measurable fashion. The measuring field generated by the magnetic field outputting means is coupled asymmetrically relative to the driver field and is easily selected by harmonic analysis from the signal of the signal coil. To this extent, the magnetic field outputting means can, for example, be configured as a coil that surrounds the actual driver and measuring part of the fluxgate sensor. On the other hand, the magnetic closure takes place via air in this case, and so the strength of the measuring signal, which depends on the magnetic flux density, is not improved.

In a preferred refinement of the fluxgate sensor, the magnetic field outputting means therefore comprises a coupling core that forms a magnetic closure in relation to the magnetic core. If use is made of a coupling core that forms a magnetic closure in relation to the magnetic core, the magnetic closure takes place via the coupling core. The magnetic conductivity is improved thereby, and so there is an increase in the measurement sensitivity and in the strength of the measuring signal.

It is, furthermore, advantageous for the magnetic core to be designed with a ring closure and to be bridged in the fashion of a bracket by the coupling core. If the magnetic core is designed with a ring closure, this results for the driver field in a closed magnetic circuit that is formed by the magnetic core. This leads to a depressed magnetic resistance, and thus overall to a higher magnetic flux density. Moreover, the geometry suppresses the signal components of the driver field. By contrast with an individual core sensor, which has the lowest sensitivity in comparison with other designs, however, the angular resolution is worsened.

In a ring core, the driver coil generates a circular flux that is oppositely directed on two opposite sides. Via the bracket-like coupling core, the measuring field is introduced uniformly into the magnetic core and generates in both limbs harmonic components that have opposite signs relative to the driver field. If signal coils are used at both limbs and are appropriately connected, the harmonic components add together, while the driver components cancel each other out. The driver field components therefore no longer occur as interference signals.

In a particularly advantageous refinement, the magnetic core has a so-called racetrack geometry, two opposite tracks of the coupling core being bridged. A racetrack geometry has the shape of a horse racetrack and corresponds approximately to a flattened oval. Such a design constitutes a compromise between sensitivity and angular resolution of the fluxgate sensor. It uses both the advantage of the closed magnetic field guidance and the high angular resolution through the straight segments of the magnetic core.

In a general design for a fluxgate sensor that has a driver core, a signal coil and a magnetic core, via which the driver coil and the signal coil are magnetically coupled, independently inventive idea the magnetic core comprises a ferrofluid. Here, this invention proceeds from the consideration that hysteresis occurring in a ferromagnetic magnetic core of the fluxgate sensor leads to an unnecessary power loss. The continuous reorientation of the magnetic moments produces heat, and so the fluxgate sensor becomes dysfunctional in particular during high-frequency use because of the temperatures that are reached. If a ferrofluid is used as magnetic core, the losses caused by hysteresis can be minimized.

In this case, ferrofluids have particles in the nano range which exhibit a very short relaxation time. By way of example, particles with a diameter of 5 nm with frequencies of more than 100 MHz relax in this way. Losses caused by hysteresis are therefore negligible at frequencies of the driver signal below 1 MHz.

At the same time, the relative permeability of a typical ferrofluid does not meet the requirements such as are placed on a magnetic core of a fluxgate sensor. For a high relative permeability, it is advantageously provided to dry the ferrofluid, there being produced a kind of piling up of particles, although the particles are not sintered.

The above described invention, in particular, can also advantageously be combined with a fluxgate sensor that comprises a spatially remote magnetic field detecting means.

It is advantageous for spatial coding in MR or MPI spectroscopy to be able to use rasterized array arrangements of the magnetic field detecting means. However, because of the required design of suitable coils it has been possible so far to construct such arrays only with a non-satisfactory spatial resolution. Since the magnetic field detecting means of the above described fluxgate sensor can, however, be constructed, in particular, as low impedance coils of small design and a low number of turns per unit length, it now becomes possible to design desired arrays for spatially resolved detection of magnetic measuring fields of MR or MPI spectroscopy.

In a particularly preferred refinement, an array arrangement having a number of fluxgate sensors of the above described type is therefore designed, in which the respective magnetic field detecting means are arranged in matrix form. Here, the magnetic field detecting means are preferably designed as small build, low impedance coils.

The above described fluxgate sensor or the above described array arrangement are, furthermore, used with particular preference for magnetic field detection of an MR or MPI spectroscopy device.

Exemplary embodiments of the invention are explained in more detail with the aid of a drawing, in which:

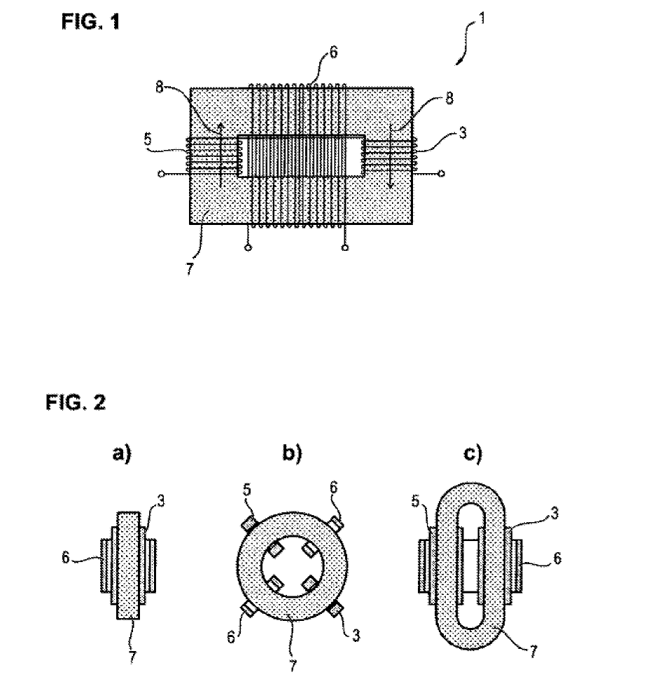

FIG. 1 shows a schematic of a fluxgate sensor with ring closure,

FIG. 2 shows various designs of a fluxgate sensor,

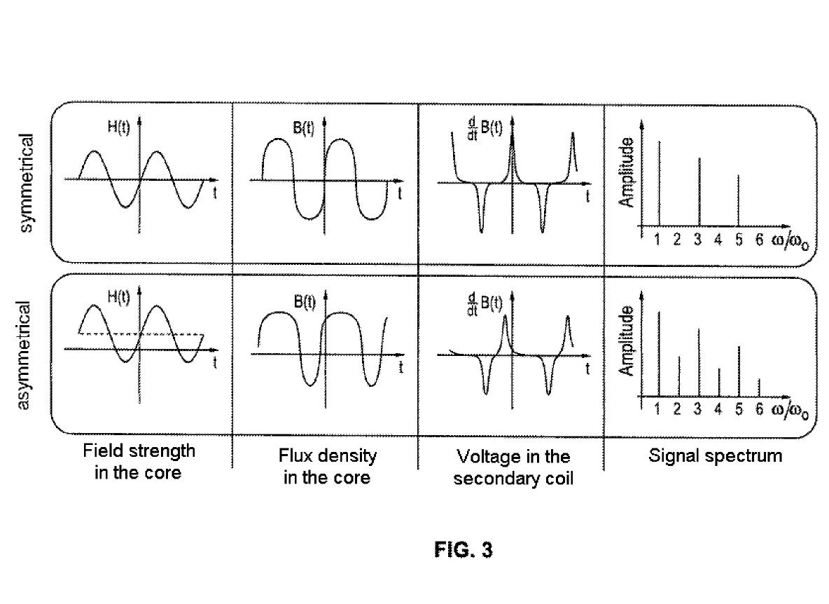

FIG. 3 shows the signal profile in a fluxgate sensor,

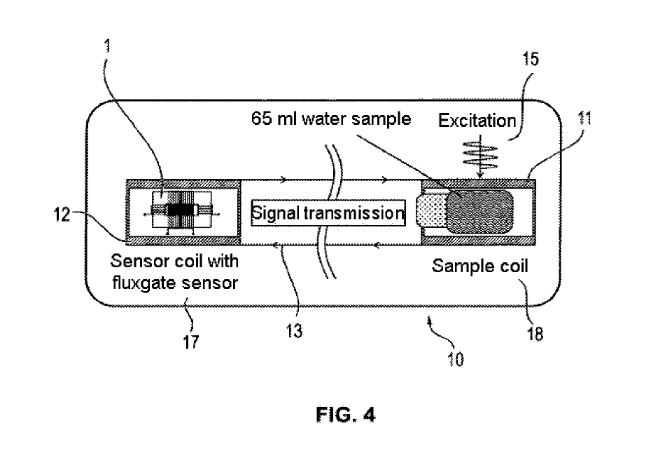

FIG. 4 shows a schematic of a fluxgate sensor with an outlying magnetic field detecting means,

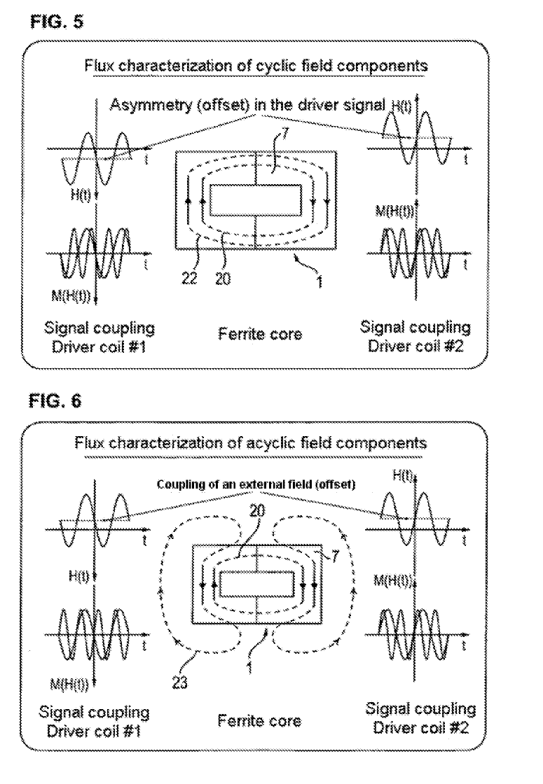

FIG. 5 shows the flux profile of cyclic field components in the magnetic core of a fluxgate sensor,

FIG. 6 shows the flux profile of acyclic field components in the magnetic core of a fluxgate sensor,

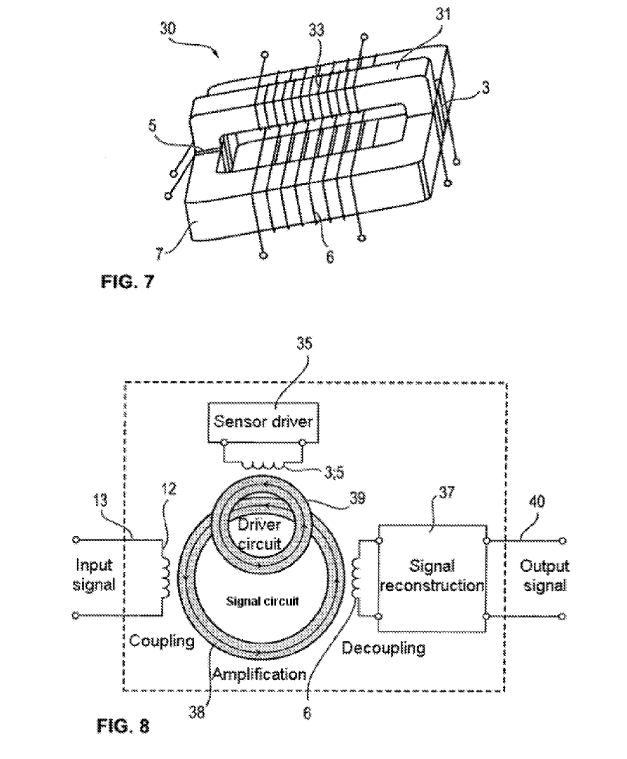

FIG. 7 shows a three-dimensional illustration of a fluxgate sensor with a bridged coupling core,

FIG. 8 shows a schematic of the operating principle of a fluxgate sensor with a coupling core,

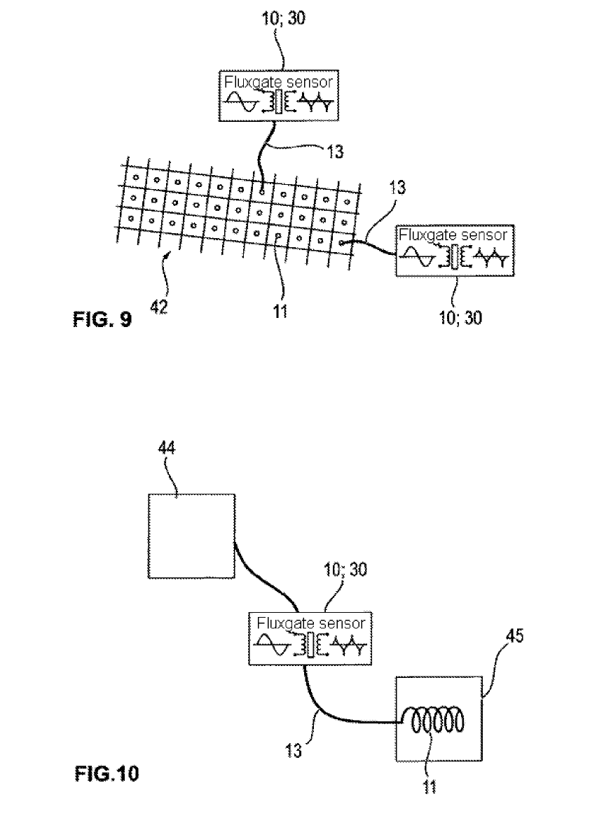

FIG. 9 shows an array arrangement with magnetic field detecting means of fluxgate sensors, and

FIG. 10 shows a schematic of an MR/MPI spectroscopy device using a fluxgate sensor for magnetic field detection.

FIG. 1 is a schematic of a fluxgate sensor 1 as it is known per se from the prior art. The fluxgate sensor 1 here comprises a first driver coil 3 and a second driver coil 5 as well as a signal coil 6. The two driver coils 3, 5 and the signal coil 6 are magnetically coupled to a ring closure via a magnetic core 7. Via the driver coils 3, 5, an alternating magnetic field is generated and coupled into the magnetic core 7. The driver field is guided here in the ring closure via the magnetic core 7, and so the flux direction 8 is directed oppositely in two opposite limbs.

The signal coil 6 is here wound over two opposite limbs, and so the effect exerted by the driver field coupled in on the decoupled measuring signal is eliminated to a certain degree. An external magnetic field permeates the magnetic core 7 uniformly. To this extent, it acts in opposite limbs of the magnetic core in respectively opposing directions on the driver field.

The alternating magnetic field, or driver field, generated by the driver coils 3, 5 is generated in such a way that the magnetization of the magnetic core 7 passes into saturation. In this way, the driver field coupled in is subjected to rectangular distortion, which leads to a measuring signal, originating from the driver field, of the signal coil 6 comprising in its spectrum only the odd harmonics. The external magnetic field or magnetic measuring field uniformly permeating the magnetic core 7 leads to an asymmetrical distortion of the driver field such that it is now the even harmonics that are contained in the measuring signal. To this extent the measuring signal can easily be distinguished from the driver signal and used to reconstruct the magnetic field to be measured.

FIG. 2 illustrates various designs of a fluxgate sensor. To be seen here respectively are the magnetic core 7 as well as the driver coils 3, 5 and signal coils 6. In accordance with FIG. 2a), the simplest design constitutes an individual core sensor. Here, the magnetic core 7 is designed as a magnetic bar. The measuring signal of such a fluxgate sensor includes all frequency components that originate both from the symmetrical driver field and from the measuring field. Consequently, this design has the least sensitivity in comparison with other designs. However, its angular resolution is not exceeded by any other geometry.

Illustrated in FIG. 2b) is a ring core sensor whose magnetic core 7 is designed as a ring. A ring core fluxgate sensor offers the greatest sensitivity, but the worst angular resolution of all designs. The high sensitivity originates from the closed magnetic circuit that is formed by the magnetic core 7. This leads to a low magnetic resistance and thus to a higher magnetic flux. However, owing to the geometry, the signal components of the driver field can be suppressed. Here, the driver coils 3, 5 generate a circular flux that is directed in opposing senses at two opposite sides of the ring core. An external magnetic field permeates the annular magnetic core 7 uniformly, and thus generates in the two limbs harmonic components that have opposite signs relative to the driver field. Given appropriate connection of the two oppositely arranged signal coils, the harmonic components add together, while the driver components cancel one another out. Consequently, the driver field components no longer occur as interference signals. The angular resolution is worsened by the constant curvature of the magnetic core 7.

In FIG. 2c), the magnetic core 7 has a so-called racetrack geometry that resembles a horse racetrack, that is to say corresponds to a flattened oval. Said racetrack geometry of the magnetic core 7 forms a compromise between sensitivity and angular resolution. The advantage of the closed magnetic field guidance is used in this case. The straight segments of the racetrack geometry serve the purpose of a high angular resolution. Here, the signal coil 6 grips the two opposite tracks of the magnetic core 7. Driver field components are eliminated in this way.

By way of example, FIG. 3 illustrates the signal profile in a fluxgate sensor for the purpose of explaining its mode of operation. If a symmetrical signal, in particular the driver signal, is coupled, this H field in the magnetic core is distorted rectangularly to form the B field by the nonlinear profile of the magnetization. Said distorted signal is tapped inductively from the signal coil as time derivative. A symmetrically coupled driver signal has the odd harmonics in the spectrum. An external magnetic field leads in the H field to an offset that leads to this extent to an additional asymmetrical distortion of the B field. The measuring signal of the signal coil, which is, in turn, tapped as a time derivative of the B field, now includes even harmonics that can be used to reconstruct the magnetic measuring field. The decoupled signal of the signal coil decomposes into a symmetrical and an asymmetrical component. The symmetrical component corresponds to the driver field and comprises the odd harmonics. The asymmetrical component corresponds to the measuring field and comprises the even harmonics.

As mentioned, because of its electromagnetic properties a fluxgate sensor can lead to a disturbance of the magnetic fields actually to be measured. To date, it has not been possible to apply it to MR or MPI spectroscopy.

FIG. 4 illustrates a fluxgate sensor 10 in the case of which the actual measuring and driver area is spatially separated from the test area. To this end, the fluxgate sensor 10 additionally comprises a magnetic field detecting means 11 that is arranged via a transmission line 13 with a magnetic field outputting means 12 in a near area of the measuring and driver segment. The actual measuring and driver segment of the fluxgate sensor 10 is formed by a fluxgate sensor 1 in accordance with FIG. 1.

Here, the magnetic field detecting means 11 is designed as a sample coil that detects the superposed magnetic field of an MR spectroscopy. In this case, an exciting magnetic field 15 irradiates in the sample area. The superposed transverse magnetization resulting from the correspondingly excited, predicting magnetic moments of the atomic nuclei is also detected via the sample coil 11.

The external magnetic field detected via the sample coil 11 is transmitted as a current via the transmission line 13, designed as electric signal line, onto the magnetic field outputting means 12 designed as sensor coil. Here, the sensor coil 12 surrounds the measuring and driver area in accordance with the fluxgate sensor 1 according to FIG. 1. Consequently, the magnetic field generated by the sensor coil 12 couples with the driver field and therefore leads to an offset, and this can be spectrally separated from the driver signal as measuring signal.

Owing to the fact that the measuring and driver area of the fluxgate sensor 10 is separated spatially from the actual test area, the magnetic field to be measured is no longer influenced by the electromagnetic properties of the fluxgate sensor 10. Owing to the high sensitivity and high low-frequency sensitivity of the fluxgate sensor 10, the sample coil 11 (and also the sensor coil 12) can additionally be designed with low impedance and a comparatively low number of turns per unit length.

FIG. 5 illustrates the flux profile of cyclic field components for a fluxgate sensor 1 in accordance with FIG. 1. A periodic driver signal is coupled in a respectively opposed sense via the two driver coils 3, 5. This leads in the fundamental wave 20 to a magnetic flux in the ring closure. Here, the flux direction is opposed in opposite tracks of the magnetic core 7. If the two driver signals on the opposite driver coils 3, 5 have an offset relative to one another, this leads to the production of a likewise cyclic harmonic 22. Its flux profile is also opposed in two opposite tracks of the magnetic coil 7. Cyclic field components therefore also propagate cyclically in the magnetic core 7.

FIG. 6 illustrates the flux profile in the magnetic core of a fluxgate sensor 1 in accordance with FIG. 1 and how it results for a coupling of acyclic field components. Once again, a periodic driver signal of respectively opposing sense is coupled via the two driver coils 3, 5. An external magnetic field now leads, however, to an offset that adds up in the same direction in opposite tracks of the magnetic core 7. However, this results in a harmonic whose flux direction is rectified in opposite tracks of the magnetic core 7. The magnetic closure of this harmonic must be performed by air by comparison with the fundamental wave 20. The magnetic core 7, which actually has a ring closure, becomes a rod core with regard to the harmonics.

FIG. 7 illustrates a fluxgate sensor 30 that implements the findings from FIGS. 5 and 6. The magnetic core 7 designed with a ring closure has the driver coils 3, 5 and a signal coil 6 according to FIG. 1. Two opposite tracks of the magnetic coil 7 are, however, now bridged in the fashion of a bracket by a coupling core 31 made from a ferromagnetic material. A coil 33 is guided around the bridge of the coupling core 31 as a magnetic field outputting means. Said coil is supplied with a current via a transmission line (not illustrated) that is tapped from a measuring coil which inductively detects an external magnetic measuring field.

Acyclic field components and/or the even harmonics in the coupling core 31 are closed in a ring with the magnetic core 7 by the bridge closure with the coupling core 31. The magnetic flux, directed in the bracket of the coupling core 31, of the measuring field, is divided in the magnetic core 7 between the two parallel limbs, and flows back again, rectified over the latter into the bracket.

The fact that the acyclic field components are guided not by air but via a ferromagnetic material in the ring closure gives rise for the measuring signal to an amplification option which was previously unrecognized. The detected magnetic measuring field decoupled from the coil 33 is guided directly into the magnetic circuit of the magnetic core 7 and detected by the signal coil 6 as harmonic signal of the even harmonics.

The basic principle of a fluxgate sensor 30 according to FIG. 7 is illustrated once more schematically in FIG. 8. A magnetic field detecting means 11 spaced apart generates an appropriate magnetic measuring field via a transmission line 13 on a magnetic field outputting means 12. Via a signal circuit 38 formed by the coupling coil 31, the generated magnetic field is guided in the ring closure on the magnetic driver circuit 39, comprising the magnetic core 7. The external acyclic magnetic field is coupled with a cyclic driver field via the driver coils 3, 5 connected to a driver stage 35. Cyclic driver field and acyclic measuring field are tapped from the signal circuit via the signal coil 6. The measuring signal is separated from the driver signal and the magnetic measuring field is reconstructed by means of a signal reconstruction 37. The appropriate output signal is tapped via an output line 40.

It can therefore be seen that the fluxgate sensor 30 operates to some extent as a magnetic field amplifier. The coupled measuring signal is amplified by means of a driver circuit 39 and the closed signal circuit 38 because of the magnetic ring closure, and can be reconstructed in the spectrum from the even harmonics.

For the purpose of spatially decoded detection of magnetic fields, FIG. 9 illustrates an array arrangement 42 in which magnetic field detecting means 11 are arranged in raster form. The magnetic field detecting means 11 are designed as small build, low impedance coils and respectively coupled via transmission lines 13 with a fluxgate sensor 10, 30 according to FIG. 4 or 7. Such an array arrangement 42 is particularly suited to spatially resolved detection of magnetic fields in MR or MPI spectroscopy.

FIG. 10 is a schematic of an MR/MPI spectroscopy device 44, fluxgate sensors 10, 30 corresponding to FIG. 4 or 7 being included for detecting the magnetic fields to be measured. Here, their respectively assigned magnetic field detecting means 11 are positioned in the actual test area 45. The detected magnetic fields are transmitted in this case to the fluxgate sensors 10, 30 via the transmission line 13. The magnetic field detecting means 11 are configured, for example, as coils or as array arrangement in accordance with FIG. 9.

### LIST OF REFERENCE SYMBOLS

1 Fluxgate sensor

3 Driver coil

5 Driver coil

6 Signal coil

7 Magnetic core

8 Flux direction

10 Fluxgate sensor

11 Magnetic field detecting means

12 Magnetic field outputting means

13 Transmission line

15 Exciting magnetic field

17 Near area

18 Remote area

20 Fundamental wave

22 Second harmonic

23 Second harmonic

30 Fluxgate sensor

31 Coupling core

33 Coil

35 Driver stage

37 Signal reconstruction

38 Signal circuit

39 Driver circuit

40 Output line

42 Array arrangement

44 MR, MPI

45 Sample space

1. A fluxgate sensor (1, 10, 30) comprising a driver coil (3, 5), a signal coil (6) and a magnetic core (7), via which the driver coil (3, 5) and the signal coil (6) are magnetically coupled, characterized in that a magnetic field detecting means (11) is provided that can be positioned in a remote area and is connected by means of a transmission line (13) to a magnetic field outputting means (12) that is positioned in the vicinity of the magnetic core (7) and whose magnetic field is superposed with the driver field.

2. The fluxgate sensor (1, 10, 30) as claimed in claim 1,
characterized in that the transmission line (13) is a flux conductor.

3. The fluxgate sensor (1, 10, 30) as claimed in claim 1,
characterized in that the transmission line (13) is an electric signal line.

4. The fluxgate sensor (1, 10, 30) as claimed in one of the preceding claims,
characterized in that the magnetic field detecting means (11) and/or the magnetic field outputting means (12) are/is of inductive design.

5. The fluxgate sensor (1, 10, 30) as claimed in claim 4,
characterized in that the magnetic field detecting means (11) and the magnetic field outputting means (12) are designed as coils.

6. The fluxgate sensor (1, 10, 30) as claimed in one of the preceding claims,
characterized in that the magnetic field outputting means (12) comprises a coupling core (31) that forms a magnetic closure in relation to the magnetic core (7).

7. The fluxgate sensor (1, 10, 30) as claimed in claim 6,
characterized in that the magnetic core (7) is designed with a ring closure and is bridged in the fashion of a bracket by the coupling core (31).

8. The fluxgate sensor (1, 10, 30) as claimed in claim 7,
characterized in that the magnetic core (7) has a racetrack geometry, two opposite tracks of the coupling core (31) being bridged.

9. The fluxgate sensor (1, 10, 30) as claimed in one of the preceding claims,
characterized in that the magnetic core (7) comprises a ferrofluid.

10. The fluxgate sensor (1, 10, 30) as claimed in one of claims 5 to 9,
characterized in that the coils are respectively of low impedance design.

11. An array arrangement (42) having a number of fluxgate sensors (1, 10, 30) as claimed in one of the preceding claims, in which the respective magnetic field detecting means (11) are arranged in matrix form.

12. The array arrangement (42) as claimed in claim 11, in which the magnetic field detecting means (11) are designed as small build, low impedance coils.

13. A device (44) for magnetic resonance spectroscopy, having a fluxgate sensor (1, 10, 30) as claimed in one of claims 1 to 10 or having an array arrangement (42) as claimed in claim 11 or 12 for the purpose of magnetic field detection.

14. A device (44) for magnetic particle imaging, having a fluxgate sensor (1, 10, 30) as claimed in one of claims 1 to 10, or having an array arrangement (42) as claimed in claim 11 or 12 for magnetic field detection.
